(19) United States
(12) Patent Application Publication
(10) Pub. No.: US 2001/0045854 A1
(43) Pub. Date: Nov. 29, 2001

(54) SEMICONDUCTOR INTEGRATED CIRCUIT AND METHOD OF COMPENSATING FOR DEVICE PERFORMANCE VARIATIONS OF SEMICONDUCTOR INTEGRATED CIRCUIT

(76) Inventor: TATSUYA SAITO, TOKYO (JP)

Correspondence Address: FOLEY & LARDNER, WASHINGTON HARBOUR, 3000 K STREET NW SUITE 500, P O BOX 25696, WASHINGTON, DC, 200078696

(21) Appl. No.: 09/089,407

(22) Filed: Jun. 3, 1998

(30) Foreign Application Priority Data
Jun. 4, 1997 (JP) 9-146732

(51) Int. Cl. H03H 11/26

(52) U.S. Cl. 327/262

(57) ABSTRACT

A semiconductor integrated circuit chip is divided into a plurality of regions each incorporating a performance variation compensating circuit. The performance variation compensating circuit supplies a power supply to a MOS FET in the region to compensate for threshold voltage variations.

### BACKGROUND OF THE INVENTION

1. Field of the Invention

The present invention relates to a semiconductor integrated circuit and a method of compensating for device performance variations of a semiconductor integrated circuit, i.e., variations of threshold voltages (VT) of MOS FETs.

2. Description of the Related Art

Semiconductor integrated circuits are normally designed in view of device performance variations. Specifically, device performance variations are presumed, and semiconductor integrated circuits are designed such that they will operate reliably for desired performance within the presumed range of device performance variations. However, since it is difficult to presume device performance variations, the period of time required to design semiconductor integrated circuits is increased, and it is necessary to give timing margins to allow semiconductor integrated circuits to operate in worst cases, the semiconductor integrated circuits thus designed tend to suffer performance reductions. There have recently been proposed variation compensation circuits capable of compensating for device performance variations of semiconductor integrated circuits to enable the semiconductor integrated circuits to exhibit a constant performance level.

A typical type of device performance variation is variation of threshold voltages of MOS FETs. Such MOS FET threshold voltage variations are caused by device manufacturing variation and operating environment variations. Device manufacturing variations occur due to variations of physical configurations and chemical compositions of semiconductor devices, and cannot essentially be avoided because manufacturing errors cannot fully be eliminated. Operating environment variations are caused by power supply voltage variations and temperature variations, and cannot essentially be avoided either because it is impossible to achieve a fully constant operating environment. Device manufacturing variations are introduced when semiconductor devices are manufactured and do not dynamically change, but remain static, in subsequent actual usage. Operating environment variations always change and are dynamic since power supply voltages and temperatures fluctuate in actual usage. Therefore, any processes of compensating for MOS FET threshold voltage variations are required to compensate for not only static variations but also dynamic variations by keeping track of such dynamic variations at all times.

One conventional arrangement for compensating for device performance variations, particularly, MOS FET threshold voltage variations, is disclosed in Japanese laid-open patent publication No. 223018/96.

FIG. 1 of the accompanying drawings shows in block form a conventional variation compensating circuit 541. As shown in FIG. 1, a control signal generating circuit 514 is supplied with electric energy from a first power supply 532 through a voltage converter 515 and also with electric energy directly from second, third, and fourth power supplies 533, 534, 535. A power supply line connected from the voltage converter 515 to the control signal generating circuit 514 and power supply lines from the second, third, and fourth power supplies 533, 534, 535 to the control signal generating circuit 514 are connected respectively as a high-potential power supply (VDD) 204, a high-potential substrate power supply (VNSUB) 205, a low-potential substrate power supply (VPSUB) 206, and a low-potential power supply (VSS) 207 to a logic circuit in the same semiconductor integrated circuit as the control signal generating circuit 514. The control signal generating circuit 514 outputs a control signal 520 to the voltage converter 515. The control signal generating circuit 514 and the voltage converter 515 jointly make up a feedback loop for keeping the potential of the VDD 204 under feedback control.

FIG. 2 of the accompanying drawings shows in block form the control signal generating circuit 514. As shown in FIG. 2, a delay circuit 614 is supplied with a clock signal 521, and the VDD 204, the VNSUB 205, the VPSUB 206, and the VSS 207 extend from the delay circuit 614. The delay circuit 614 delays the clock signal 521 by a time determined by potentials supplied by the VDD 204, the VNSUB 205, the VPSUB 206, and the VSS 207, and outputs the delayed clock signal 521. A phase comparator 611 is supplied with the clock signal 521 not delayed by the delay circuit 614 and the clock signal 521 delayed by the delay circuit 614, and outputs a leading/lagging pulse proportional to the phase difference between the supplied clock signals. A charge pump circuit 612 is supplied with the output pulse from the phase comparator 611, and charges or discharges an electric charge depending on the duration of the supplied pulse. A low-pass filter 613 is supplied with an output signal from the charge pump circuit 612, removes high-frequency components from the supplied signal, and outputs a DC voltage as the control signal 522.

The control signal generating circuit 514 operates as follows: If there is a phase difference between the delayed clock signal 521 outputted by the delay circuit 614 and the original clock signal 521, the DC voltage of the control signal 522 is increased or reduced by the phase comparator 611, the charge pump circuit 612, and the low-pass filter 613. In response to the increase or reduction in the DC voltage, the voltage converter 515 changes the potential of the VDD 204. When the potential of the VDD 204 is changed, the delay caused by the delay circuit 614 is changed, bringing the phase of the delayed clock signal 521 outputted by the delay circuit 614 closer to the phase of the original clock signal 521. The above operation is repeated until there is no phase difference between the delayed clock signal 521 outputted by the delay circuit 614 and the original clock signal 521. When there is no phase difference, i.e., the delay caused by the delay circuit 614 is equal to one period of the clock signal 521, the control signal generating circuit 514 operates stably under a steady condition.

FIG. 3 of the accompanying drawings shows the delay circuit 614 in detail. As shown in FIG. 3, a plurality of inverters, each comprising a P-channel MOS (PMOS) 401 and an N-channel MOS (NMOS) 403, are connected in series with each other. The PMOS 401 has a source connected to the VDD 204 and a substrate connected to the VNSUB 205, and the NMOS 403 has a source connected to the VSS 207 and a substrate connected to the VPSUB 206. The threshold voltage of a MOS is a function of a source potential and a substrate potential. In the NMOS 403, the threshold voltage is higher if the source potential is higher than the substrate potential, and lower if the source potential is lower than the substrate potential. In the PMOS 401, the threshold voltage is higher if the source potential is lower than the substrate potential, and lower if the source potential is higher than the substrate potential. Therefore, when the source potential or the substrate potential or both are changed, the threshold voltage is changed to increase or reduce the drain current. Based on this principle, the delay circuit 614 changes the propagation delay time from an input terminal 701 to an output terminal 702 by changing any one of the potentials of the VDD 204, the VNSUB 205, the VPSUB 206, and the VSS 207 or a combination of these potentials.

Consequently, the variation compensating circuit 541 automatically controls, using a feedback control loop, any one of the potentials of the VDD 204, the VNSUB 205, the VPSUB 206, and the VSS 207 or a combination of these potentials in order that the delay time of the delay circuit 614 is equalized to one period of the clock signal 521. It is important to understand that the feedback control reference is provided by the stable clock signal supplied from outside of the semiconductor integrated circuit at all times during the feedback control process, and hence the delay time of the delay circuit 614 is always kept constant with respect to device manufacturing variations and operating environment variations which fluctuate in actual usage.

Although not shown, the logic circuit in the same semiconductor integrated circuit as the delay circuit 614 is connected to the same power supplies as the delay circuit 614. Stated otherwise, the logic circuit shares the VDD 204, the VNSUB 205, the VPSUB 206, and the VSS 207 with delay circuit 614. Since the propagation delay time of the delay circuit 614 is kept constant so as to be equal to one period of the clock signal 521, the propagation delay time of the logic circuit in the same semiconductor integrated circuit is also kept constant regardless of device manufacturing variations and operating environment variations, and the logic circuit maintains a constant performance level at all times.

Inasmuch as the conventional variation compensating circuit described above is mounted as a single circuit on the semiconductor integrated circuit, it cannot sufficiently compensate for variations if the semiconductor integrated circuit has a large area. Specifically, in a semiconductor integrated circuit having a large area, threshold voltages vary even on the same chip. Typically, threshold voltage variations are up to ten and several mV on a chip having each side of 15 mm with a gate length of 0.35 μm. The single conventional variation compensating circuit on the chip cannot sufficiently compensate for such threshold voltage variations. The conventional variation compensating circuit is effective to compensate for threshold voltage variations only with respect to logic circuits near the variation compensating circuit.

### SUMMARY OF THE INVENTION

It is therefore an object of the present invention to provide a semiconductor integrated circuit and a method of compensating for device performance variations of a semiconductor integrated circuit having a large area.

According to an aspect of the present invention, there is provided a method of compensating for device performance variations of a semiconductor integrated circuit, comprising the steps of dividing a chip carrying MOS FETs for performing functions of a semiconductor integrated circuit into a plurality of regions, and incorporating performance variation compensating circuits for supplying a power supply to the MOS FETs to compensate for variations in threshold voltages of the MOS FETs, into the divided regions respectively, so that device performance variations in the regions which incorporate the performance variation compensating circuits will be compensated for by the performance variation compensating circuits.

According to another aspect of the present invention, there is provided a method of compensating for device performance variations of a semiconductor integrated circuit, comprising the steps of dividing a chip carrying MOS FETs for performing functions of a semiconductor integrated circuit into a plurality of regions, and incorporating performance variation compensating circuits for supplying a power supply to the MOS FETs to compensate for variations in threshold voltages of the MOS FETs, into those of the divided regions which contribute to the performance of the chip respectively, so that device performance variations in the regions which incorporate the performance variation compensating circuits will be compensated for by the performance variation compensating circuits.

According to still another aspect of the present invention, there is provided a semiconductor integrated circuit comprising a chip carrying MOS FETs for performing functions of a semiconductor integrated circuit, the chip being divided into a plurality of regions, and performance variation compensating circuits incorporated into the regions respectively, for supplying a power supply to the MOS FETs to compensate for variations in threshold voltages of the MOS FETs, respectively.

According to yet still another aspect of the present invention, there is provided a semiconductor integrated circuit comprising a chip carrying MOS FETs for performing functions of a semiconductor integrated circuit, the chip being divided into a plurality of regions, and performance variation compensating circuits incorporated only into those of the divided regions which greatly contribute to the performance of the chip respectively, for supplying a stable power supply to the MOS FETs to compensate for variations in threshold voltages of the MOS FETS.

With the above arrangement, the chip of the semiconductor integrate circuit is divided into a plurality of regions each incorporating a performance variation compensating circuit for individually controlling circuit devices in the region. Since the region where device performance variations are to be compensated for is localized, device performance variations of a semiconductor integrated circuit having a large areas can sufficiently be compensated for.

The above and other objects, features, and advantages of the present invention will become apparent from the following description based on the accompanying drawings which illustrate examples of preferred embodiments of the present invention.

### BRIEF DESCRIPTION OF THE DRAWINGS

FIG. 1 is a block diagram of a conventional variation compensating circuit for compensating for device performance variations of semiconductor integrated circuits;

FIG. 2 is a block diagram of a control signal generating circuit in the conventional variation compensating circuit shown in FIG. 1;

FIG. 3 is a circuit diagram of a delay circuit in the control signal generating circuit shown in FIG. 2;

FIG. 4 is a flowchart of a method of compensating for device performance variations of a semiconductor integrated circuit according to a first embodiment of the present invention;

FIG. 5 is a schematic plan view of a semiconductor integrated circuit to which the method of compensating for device performance variations as shown in FIG. 4 is applied;

FIG. 6 is a schematic plan view of a first region of the semiconductor integrated circuit shown in FIG. 4;

FIG. 7 is a flowchart of a method of compensating for device performance variations of a semiconductor integrated circuit according to a second embodiment of the present invention;

FIG. 8 is a schematic plan view of a semiconductor integrated circuit to which the method of compensating for device performance variations as shown in FIG. 7 is applied; and

FIG. 9 is a schematic plan view of a third region of the semiconductor integrated circuit shown in FIG. 8.

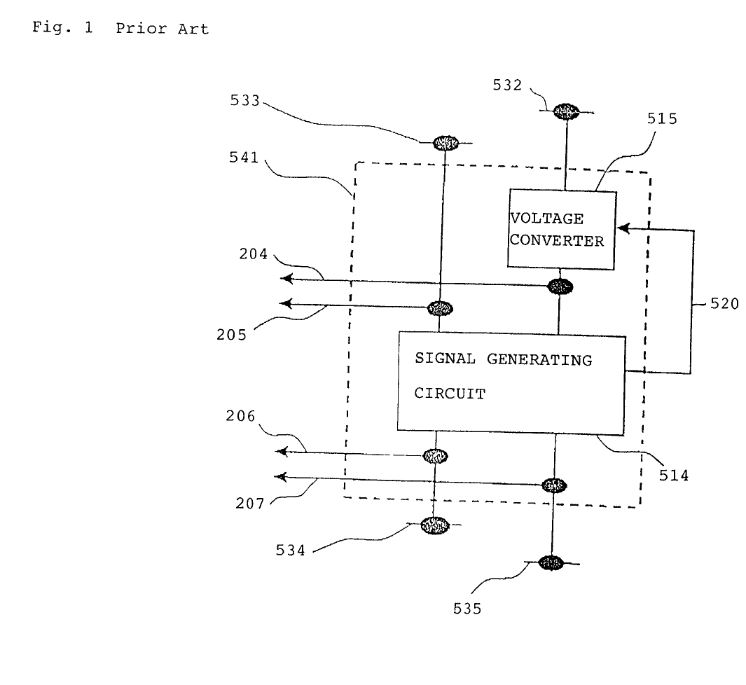

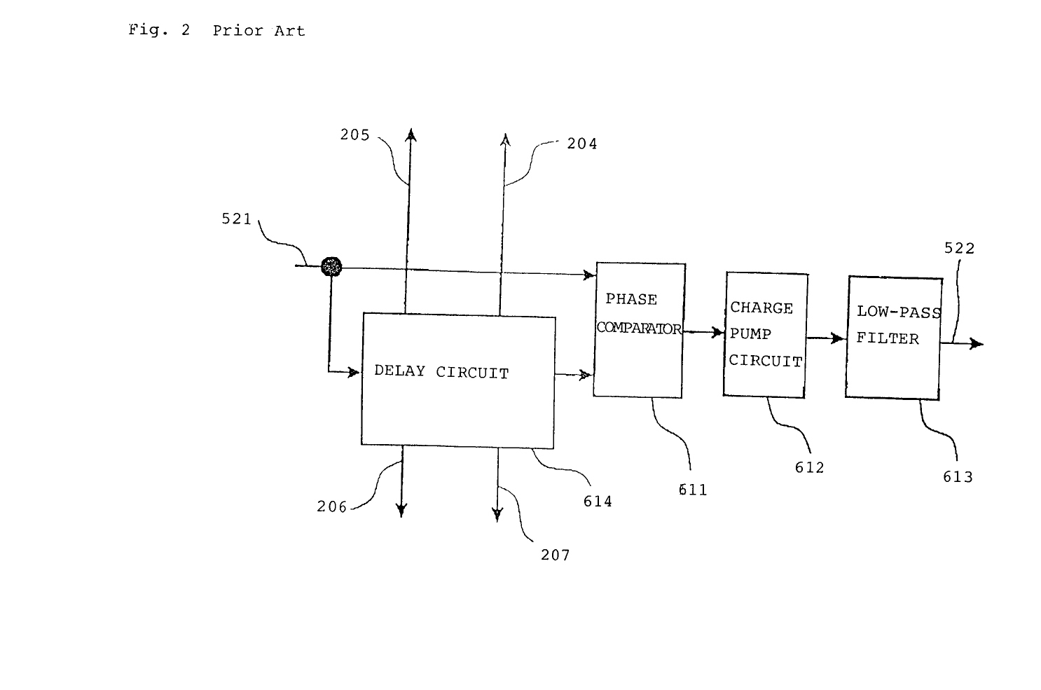

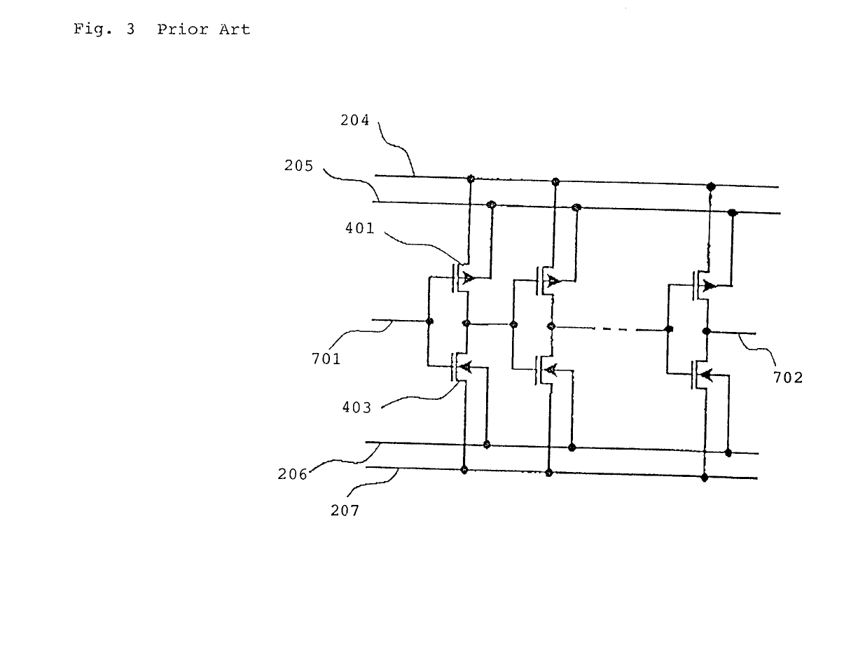

### DETAILED DESCRIPTION OF THE PREFERRED EMBODIMENTS

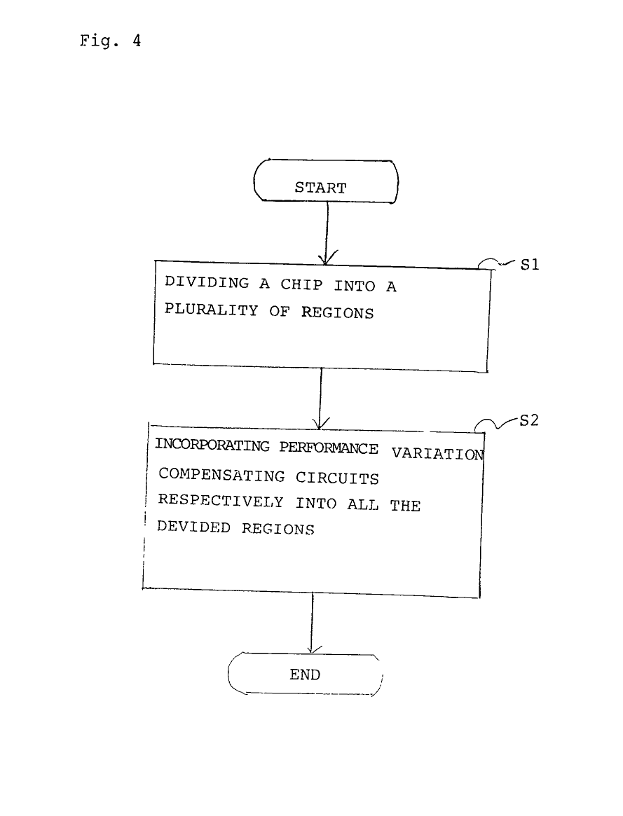

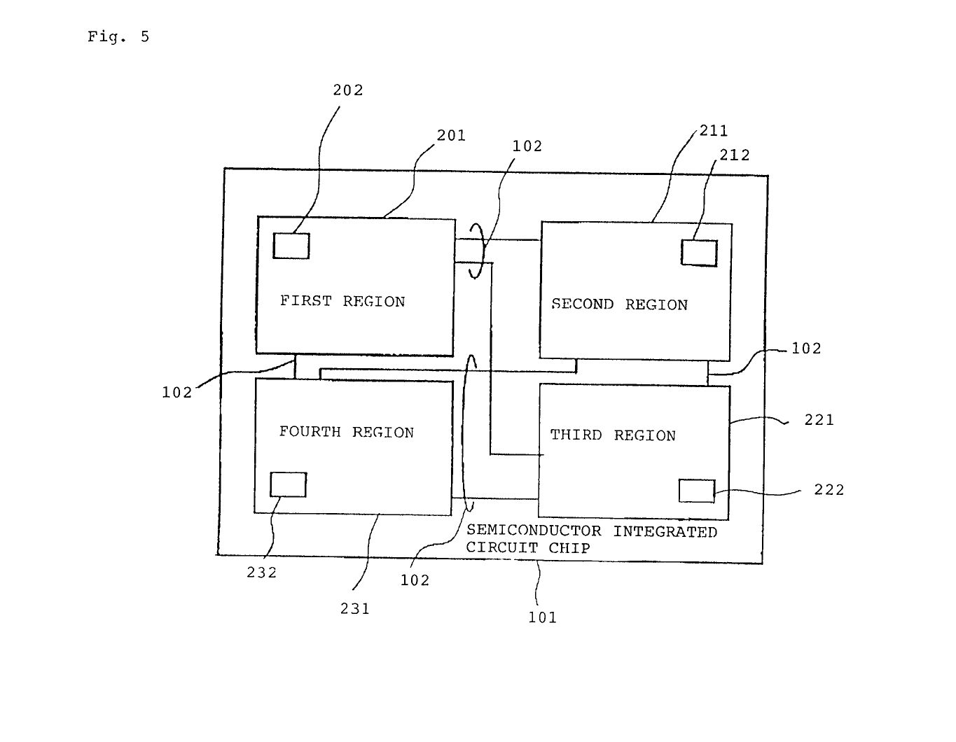

According to a method of compensating for device performance variations of a semiconductor integrated circuit according to a first embodiment of the present invention, as shown in FIGS. 4 and 5, a semiconductor integrated circuit chip 101 is divided into a plurality of regions including a first region 201, a second region 211, a third region 221, and a fourth region 231 in step S1. The divided regions 201, 211, 221, 231 are interconnected by interconnections 102 for an exchange of signals therebetween. Although not shown, at least one of VDD, NSUB, VPSUB, and VSS interconnections is provided in each of the regions 201, 211, 221, 231, separately from those in the other regions. The semiconductor integrated circuit chip 101 may be designed such that the regions 201, 211, 221, 231 have equal areas or the divided regions comprise their respective functional blocks of logic circuits on the chip insofar as the regions will not be extremely large.

Then, a first performance variation compensating circuit 202, a second performance variation compensating circuit 212, a third performance variation compensating circuit 222, and a fourth performance variation compensating circuit 232 are provided respectively in all the divided regions, i.e., the first region 201, the second region 211, the third region 221, and the fourth region 231, for compensating for device performance variations in these regions in step S2. Each of the performance variation compensating circuits 202, 212, 222, 232 is equivalent to the conventional performance variation compensating circuit described above.

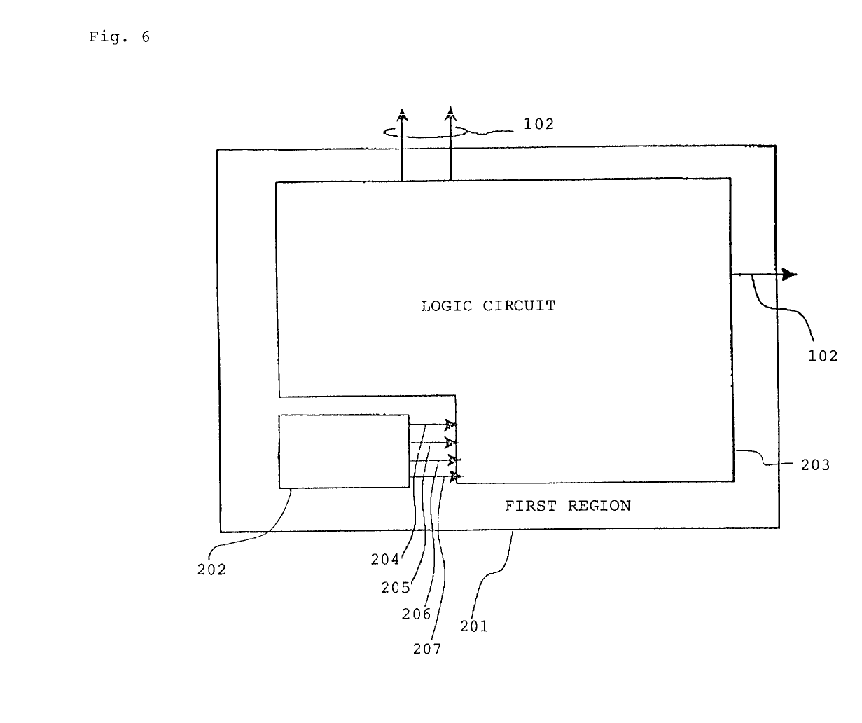

The first region 201, for example, will be described below with reference to FIG. 6. As shown in FIG. 6, the first region 201 includes the first performance variation compensating circuit 202 and a logic circuit 203. The logic circuit 203 serves to perform the functions of the semiconductor integrated circuit. The first performance variation compensating circuit 202 provides the VDD 204, the VNSUB 205, the VPSUB 206, and the VSS 207 which apply power supply potentials to the logic circuit 203. The VDD 204, the VNSUB 205, the VPSUB 206, and the VSS 207 are controlled in the same manner as with the conventional variation compensating circuit. The second region 211, the third region 221, and the fourth region 231 are identical in structure to the first region 201.

As described above, the semiconductor integrated circuit chip to which the method according to the first embodiment of the present invention is divided into a plurality of regions each having a performance variation compensating circuit for compensating device performance variations in the region. Therefore, even if there are threshold voltage variations on one chip in a semiconductor integrated circuit having a large area, since variation control is localized according to the method of the resent invention, all device performance variations in the semiconductor integrated circuit can sufficiently be compensated for.

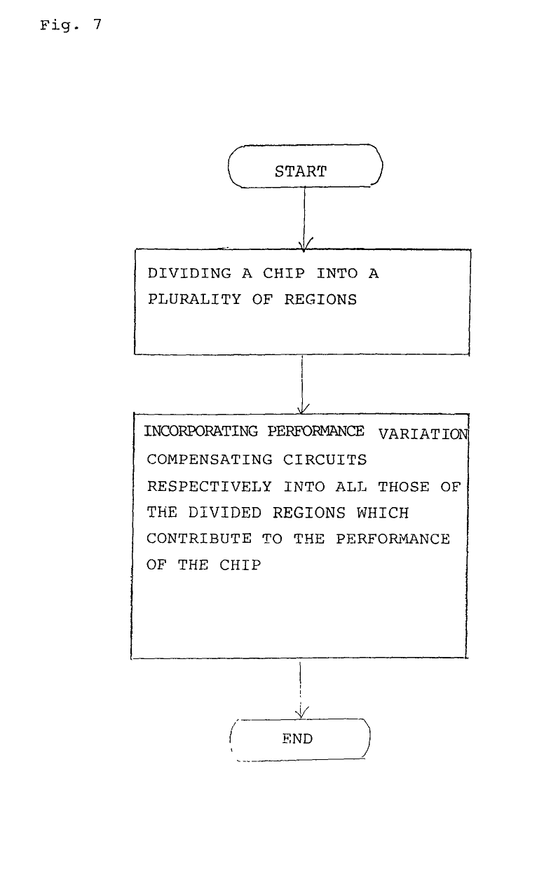

According to a method of compensating for device performance variations of a semiconductor integrated circuit according to a second embodiment of the present invention, as shown in FIGS. 7 and 8, a semiconductor integrated circuit chip 101 is divided into a plurality of regions including a first region 201, a second region 211, a third region 221₁, and a fourth region 231₁ in step S11. The divided regions 201, 211, 221₁, 231₁ are interconnected by interconnections 102 for an exchange of signals therebetween. Although not shown, at least one of VDD, NSUB, VPSUB, and VSS interconnections is provided in each of the first and second regions 201, 211, separately from those in the other regions. However, the third region 221₁ and the fourth region 231₁ have none of VDD, NSUB, VPSUB, and VSS interconnections therein, but share those interconnections with other regions. For example, the third region 221₁ and the fourth region 231₁ share those interconnections with each other. The semiconductor integrated circuit chip 101 may be divided such that the regions 201, 211, 221₁, 231₁ have equal areas or the divided regions comprise their respective functional blocks of the logic circuits on the chip insofar as the regions will not be extremely large.

Then, a first performance variation compensating circuit 202 and a second performance variation compensating circuit 212 are provided respectively in those divided regions which are capable of contributing to the performance of the semiconductor integrated circuit chip, i.e., the first region 201 and the second region 211 in FIG. 8, for compensating for device performance variations in these regions in step S2. Each of the performance variation compensating circuits 202, 212 is equivalent to the conventional performance variation compensating circuit described above. No performance variation compensating circuit is provided in the third region 221₁ and the fourth region 231₁. Regions where a performance variation compensating circuit is to be provided should be those regions which are capable of contributing to the performance of the semiconductor integrated circuit chip, e.g., those regions which have many gate stages and include a critical path whose signal propagation delay determines the chip performance.

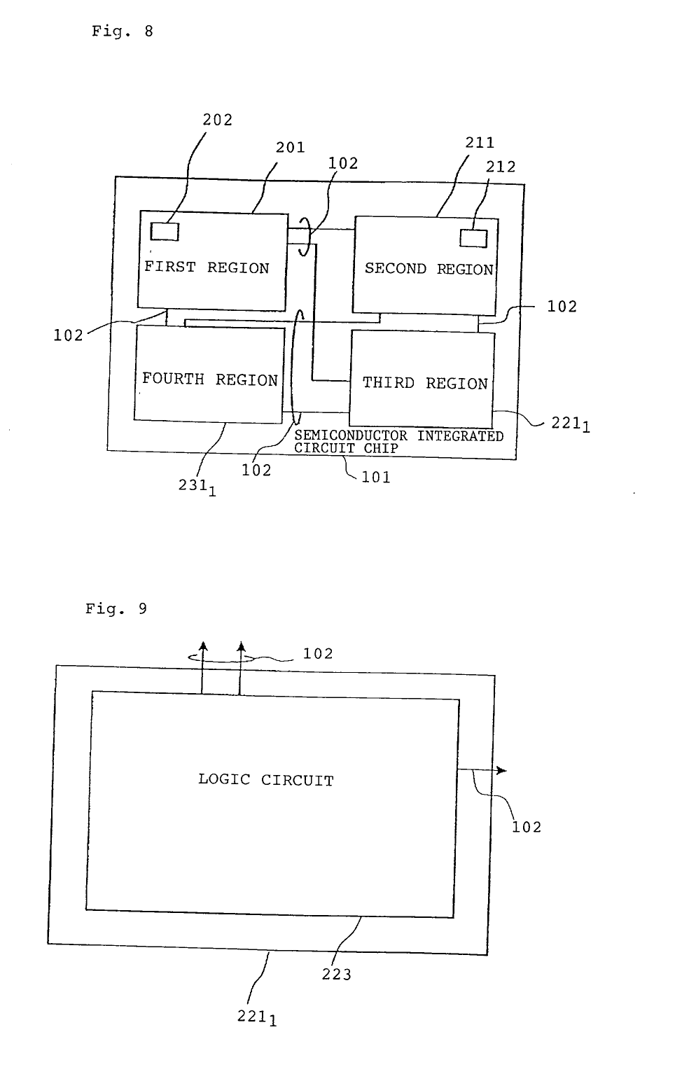

The first region 201 and the second region 211 are shown in detail in FIG. 8. No performance variation compensating circuit is provided in the third region 221₁ and the fourth region 231₁. FIG. 9 shows in detail the third region 221₁ as a typical region where no performance variation compensating circuit is provided. As shown in FIG. 9, the third region 221₁ comprises only a logic circuit 223 for performing the functions of the semiconductor integrated circuit. Therefore, no device performance variations are compensated for in the third region 221₁, and the third region 221₁ operates with device performance variations including device manufacturing variations and operating environment variations. Since, however, the degree of contribution of the third region 221₁ to the performance of the semiconductor integrated circuit chip is assumed to be small, any device performance variations of the third region 221₁ do not adversely affect the overall performance of the semiconductor integrated circuit.

As described above, the semiconductor integrated circuit chip to which the method according to the second embodiment of the present invention is divided into a plurality of regions, and only some of the divided regions have respective performance variation compensating circuits for compensating for device performance variations in the regions, whereas the other divided regions do not have performance variation compensating circuits, but are allowed to suffer device performance variations. According to the second embodiment, therefore, the number of performance variation compensating circuits is relatively small, and any increase in the chip region caused by incorporation of performance variation compensating circuits is minimized.

It is to be understood, however, that although the characteristics and advantages of the present invention have been set forth in the foregoing description, the disclosure is illustrative only, and changes may be made in the arrangement of the parts within the scope of the appended claims.

What is claimed is:

1. A method of compensating for device performance variations of a semiconductor integrated circuit, comprising the steps of:
dividing a chip carrying MOS FETs for performing functions of a semiconductor integrated circuit into a plurality of regions; and
incorporating performance variation compensating circuits for supplying a stable power supply to the MOS FETs to compensate for variations in threshold voltages of the MOS FETs, into the divided regions respectively, so that device performance variations in the regions which incorporate the performance variation compensating circuits will be compensated for by said performance variation compensating circuits.

2. A method of compensating for device performance variations of a semiconductor integrated circuit, comprising the steps of:
dividing a chip carrying MOS FETs for performing functions of a semiconductor integrated circuit into a plurality of regions; and
incorporating performance variation compensating circuits for supplying a stable power supply to the MOS FETs to compensate for variations in threshold voltages of the MOS FETs, only into those of the divided regions which contribute greatly to the performance of said chip respectively, so that device performance variations in the regions which incorporate the performance variation compensating circuits will be compensated for by said performance variation compensating circuits.

3. A method according to claim 1, wherein said step of dividing comprises the step of dividing the chip such that the divided regions have equal areas.

4. A method according to claim 1, wherein said step of dividing comprises the step of dividing the chip such that the divided regions comprise their respective functional blocks of logic circuit on said chip.

5. A method according to claim 1, wherein said step of dividing comprises the step of dividing the chip such that each of the regions has at least one of interconnections of a high-potential power supply, a high-potential substrate power supply, a low-potential substrate power supply, and a low-potential power supply, separately from interconnections in the other regions.

6. A method according to claim 2, wherein said step of dividing comprises the step of dividing the chip such that the divided regions will have equal areas.

7. A method according to claim 2, wherein said step of dividing comprises the step of dividing the chip such that the divided regions comprise their respective functional blocks of logic circuits on said chip.

8. A method according to claim 2, wherein said step of dividing comprises the step of dividing the chip such that each of the regions has at least one of interconnections of a high-potential power supply, a high-potential substrate power supply, a low-potential substrate power supply, and a low-potential power supply, separately from interconnections in the other regions.

9. A method according to claim 2, wherein said step of incorporating performance variation compensating circuits comprises the step of incorporating the performance variation compensating circuits into those of the regions which have a number of gate stages and include a critical path whose signal propagation delay determines the performance of said chip.

10. A semiconductor integrated circuit comprising:
a chip carrying MOS FETs for performing functions of a semiconductor integrated circuit, said chip being divided into a plurality of regions; and
performance variation compensating circuits incorporated in all of said divided regions respectively, for supplying a stable power supply to the MOS FETs to compensate for variations in threshold voltages of the MOS FETs, respectively.

11. A semiconductor integrated circuit comprising:
a chip carrying MOS FETs for performing functions of a semiconductor integrated circuit, said chip being divided into a plurality of regions; and
performance variation compensating circuits incorporated into those of the divided regions which contribute greatly to the performance of said chip respectively, for supplying a power supply to the MOS FETs to compensate for variations in threshold voltages of the MOS FETs.

12. A semiconductor integrated circuit 10, wherein said chip is divided such that the divided regions have equal areas.

13. A semiconductor integrated circuit 10, wherein said chip is divided such that the divided regions comprise their respective functional blocks of logic circuits on said chip.

14. A semiconductor integrated circuit 10, wherein said chip is divided such that each of the regions has at least one of interconnections of a high-potential power supply, a high-potential substrate power supply, a low-potential substrate power supply, and a low-potential power supply, separately from interconnections in the other regions.

15. A semiconductor integrated circuit 11, wherein said chip is divided such that the divided regions have equal areas.

16. A semiconductor integrated circuit 11, wherein said chip is divided such that the divided regions comprise their respective functional blocks of logic circuits on said chip.

17. A semiconductor integrated circuit 11, wherein said chip is divided such that each of the regions has at least one of interconnections of a high-potential power supply, a high-potential substrate power supply, a low-potential substrate power supply, and a low-potential power supply, separately from interconnections in the other regions.

18. A semiconductor integrated circuit 11, wherein said performance variation compensating circuits are incorporated in those of the regions which have a number of gate stages and include a critical path whose signal propagation delay determines the performance of said chip.
